(19) United States
(12) Patent Application Publication
(10) Pub. No.: US 2009/0269494 A1
(43) Pub. Date: Oct. 29, 2009

(54) FILM-FORMING APPARATUS, FILM-FORMING METHOD AND RECORDING MEDIUM

(75) Inventors: Tsuyoshi Takahashi, Yamanashi (JP); Shintaro Aoyama, Yamanashi (JP); Takahiro Shinada, Yamanashi (JP); Masato Kawakami, Yamanashi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 11/910,508

(22) PCT Filed: Apr. 3, 2006
(86) PCT No.: PCT/JP2006/307058

§ 371 Date: Oct. 2, 2007

(30) Foreign Application Priority Data
Apr. 4, 2005 (JP) 2005-107667

(51) Int. Cl. C23C 16/22; C23C 16/46

(52) U.S. Cl. 427/255.28; 118/728

(57) ABSTRACT

A film forming apparatus comprises a processing chamber for holding therein a to-be-processed substrate, a first gas supplying means for supplying into the processing chamber a first vapor source including a metal alkoxide having a tertiary butoxyl group as a ligand, and a second gas supplying means for supplying into the processing chamber a second vapor source including a silicon alkoxide source, wherein the first gas supplying means and the second gas supplying means are connected to a pre-reaction means for causing pre-reactions of the first vapor source and the second vapor source, and the film forming apparatus is configured to supply the first vapor source and the second vapor source after the pre-reactions into the processing chamber.

### TECHNICAL FIELD

The present invention generally relates to film forming apparatuses for producing semiconductor devices, and more particularly to a film forming apparatus for producing a high-speed semiconductor device having a high-K dielectric film with a very large scale integration.

In current ultra-high-speed semiconductor devices, it is becoming possible to realize a gate length of 0.1 μm or less due to the progress made in the large scale integration. Generally, the operation speed of the semiconductor device improves with the large scale integration, but in the case of the semiconductor device having the very large scale integration, it is necessary to reduce the thickness of the gate insulator film according to a scaling rule, due to the shortening of the gate length caused by miniaturization.

### BACKGROUND ART

However, when the gate length becomes 1 μm or less, it is necessary to set the thickness of the gate insulator film to 1 nm to 2 nm or less than 1 nm when the conventional thermal oxidation film is used for the gate insulator film. But in the case of such a gate insulator film that is extremely thin, the tunneling current increases, and as a result, it is impossible to avoid the problem of the increasing gate leak current.

For this reason, there conventionally are proposals to use for the gate insulator material a high dielectric constant material (so-called high-K material) such as Ta₂O₅, Al₂O₃, ZrO₂, HfO₂, ZrSiO₄ and HfSiO₄ having a dielectric constant that is considerably large compared to that of the thermal silicon oxide film By using such a high dielectric constant material, it becomes possible to make the physical thickness of the gate insulator film large while maintaining the EOT (SiO₂ capacitance equivalent thickness) small. Consequently, even in an ultra-high-speed semiconductor device having an extremely short gate length of 0.1 μm or less, it is possible to use a gate insulator film having a physical thickness on the order of approximately 10 nm, and suppress the gate leak current caused by the tunneling effect.

Particularly the metal silicate materials such as ZrSiO₄ and HfSiO₄ greatly increase the crystallization temperature when compared to the oxide materials such as ZrO₂ and HfO₂, although the dielectric constant slightly decreases. Hence, the metal silicate materials effectively suppress the crystallization within the film even when the thermal processing used in the production process of the semiconductor device is carried out. Accordingly, the metal silicate materials are regarded as being extremely suited for use as the high-K gate insulator film material of the high-speed semiconductor device.

Conventionally, it is known to form such a high-K gate insulator film by the Atomic Layer Deposition (ALD) or the Metal Organic (MO) CVD. Particularly when the ALD, that forms a film by depositing one atomic layer at a time, is used, it is possible to form an arbitrary composition profile within the film. For example, a Japanese Laid-Open Patent Application No. 2001-284344 proposes forming a ZrSiO₄ gate insulator film by using the ALD technique so as to form a composition profile in which the gate insulator film in a vicinity of an interface between the gate insulator film and a silicon substrate is Si rich and the gate insulator film becomes Zr rich in a direction further away from the interface. On the other hand, according to the ALD, the source gas is switched for every one atomic layer deposition, and the deposition is carried out by inserting a purge process between successive atomic layer depositions. For this reason, the ALD takes time, and there is a problem in that the production throughput of the semiconductor device deteriorates.

According to the MOCVD, it is possible to greatly improve the production throughput of the semiconductor device, because the deposition is carried out in one operation using the metal organic compound source. For this reason, in order to improve the productivity, it is preferable to use the MOCVD compared to the ALD. In addition, the film forming apparatus using the MOCVD has a simpler structure than the film forming apparatus using the ALD. Therefore, the apparatus using the MOCVD is more advantageous than the apparatus using the ALD in terms of the cost of the apparatus itself and the cost required to maintain and manage the apparatus.

FIG. 1 schematically shows an example of the structure of the film forming apparatus using the MOCVD.

In FIG. 1, a film forming apparatus 10, that is an MOCVD apparatus, has a processing chamber 12 that is exhausted by a pump 11, and a holding base 12A that holds a substrate W to be processed (hereinafter referred to as a to-be-processed substrate W) is provided within the processing chamber 12.

A shower head 12S having a plurality of openings (gas ejection holes) 12P is provided within the processing chamber 12 so as to confront the to-be-processed substrate W. The shower head 12S is connected to a line 12a that supplies oxygen gas via an MFC (Mass Flow Controller) which is not shown and a valve V11. In addition, the shower head 12S is connected to a line 12b that supplies a metal organic compound source gas such as Hafnium Tetratertiary Butoxide (HTB), for example, via an MFC which is not shown and a valve V12.

The oxygen gas and the metal organic compound source gas pass through the respective passages within the shower head 12S, and are ejected to processing space within the processing chamber 12 via the openings 12P that are formed in the surface of the shower head 12S confronting the silicon substrate W.

A HfO₂ film is formed on the to-be-processed substrate W that is heated by a heating means 12h, such as a built-in heater of the holding base 12A.

Patent Document 1: Japanese Laid-Open Patent Application No. 2001-284344

Patent Document 2: International Publication WO03/049173

Patent Document 3: U.S. Pat. No. 6,551,948

### DISCLOSURE OF THE INVENTION

### Problems to be Solved by the Invention

However, in the case of the film forming apparatus described above, there was a problem in that the source gas, for example, is consumed at a location other than the to-be-processed substrate before reaching the to-be-processed substrate.

FIG. 2 is a diagram showing a relationship of the thickness of the HfO₂ film formed on the to-be-processed substrate with respect to the temperature of the to-be-processed substrate, for a case where the HfO₂ film is formed on the to-be-processed substrate by the film forming apparatus shown in FIG. 1.

As shown in FIG. 2, up to the to-be-processed substrate temperature of approximately 350° C., the thickness of the film that is formed has a tendency of increasing with increasing to-be-processed substrate temperature. It may be regarded that this tendency is due to the thermal decomposition of the source gas that is accelerated with increasing to-be-processed substrate temperature.

However, when the to-be-processed substrate temperature becomes 350° C. or higher, it may be seen that the thickness of the HfO₂ film formed on the to-be-processed substrate decreases with respect to increasing to-be-processed substrate temperature.

When the reactions of the temperature, the source gas and the oxidation gas are taken into consideration, it may be expected that the thickness of the HfO₂ film that is formed on the to-be-processed substrate increases with increasing temperature of the to-be-processed substrate, in a temperature region of approximately 300° C. to approximately 400° C. In addition when the temperature of the to-be-processed substrate is further increased, it may be expected that the effect of increasing the film thickness with increasing temperature converges when the temperature of the to-be-processed substrate is in a vicinity of 400° C., and that the film thickness becomes approximately constant with respect to the temperature increase when the temperature of the to-be-processed substrate is 400° C. or higher.

But actually, contrary to the above expectations, there is a tendency for the film thickness to decrease with increasing temperature when the temperature of the to-be-processed substrate is in a temperature region exceeding 350° C. Such a tendency is difficult to explain when only the reactions on the to-be-processed substrate are taken into consideration, and it may be regarded that there is a high possibility of the source gas being consumed at a location other than on the to-be-processed substrate.

For example, in the case of the film forming apparatus 10 described above that forms the film, the shower head 12S is maintained to a temperature of approximately 100° C., and since this temperature is lower than or equal to the decomposition temperature of the source gas, no decomposition and no consumption (film formation) of the source gas will occur. For this reason, it may be regarded that the molecules of the source gas, that is output from the openings 12P and reaches the to-be-processed substrate, are heated in this space between the openings 12P and the to-be-processed substrate, to thereby cause a partial decomposition of the molecules.

The activated intermediate (precursor) that is generated by the decomposition of the source gas diffuses and mainly adheres or forms a film on the shower head existing nearby. When the shower head was examined after actually forming the film, it was observed that a film, believed to correspond to the decrease in the amount of film formed on the to-be-processed substrate, was formed on the surface of the shower head confronting the to-be-processed substrate.

When such a film formation occurs at the location other than on the to-be-processed substrate, particles caused by the film formation are generated, to thereby contaminate the film that is formed on the to-be-processed substrate. In addition, particularly the high-K dielectric film such as the HfO₂ film is difficult to remove by the cleaning of the conventional CVD, and when the film is formed on the shower head or the like, it is necessary to stop the film forming apparatus and replace the parts, such as the shower head, on which the film is formed.

For this reason, the maintenance of the film forming apparatus requires time, and the operation rate of the film forming apparatus may deteriorate and make it difficult to form the film efficiently.

On the other hand, the source gas that is used to form the high-K dielectric film is expensive in most cases, and if the amount of the source gas not contributing to the film formation on the to-be-processed substrate increases, that is, if the utilization efficiency of the source gas decreases, there was a problem in that the amount of the source gas that is consumed increases and the cost of the film formation increases.

Accordingly, it is a general object of the present invention to provide a novel and useful film forming apparatus, film forming method and recording medium recorded with the film forming method, in which the problem described above is eliminated.

Another and more specific object of the present invention is to enable a film formation by MOCVD, with a satisfactory utilization efficiency of the source gas and a high productivity.

### Means of Solving the Problems

According to a first aspect of the present invention, a film forming apparatus comprises a processing chamber for holding therein a to-be-processed substrate, a first gas supplying means for supplying into the processing chamber a first vapor source including a metal alkoxide having a tertiary butoxyl group as a ligand, and a second gas supplying means for supplying into the processing chamber a second vapor source including a silicon alkoxide source, wherein the first gas supplying means and the second gas supplying means are connected to a pre-reaction means for causing pre-reactions of the first vapor source and the second vapor source, and the film forming apparatus is configured to supply the first vapor source and the second vapor source after the pre-reactions into the processing chamber, so as to solve the problem described above.

According to a second aspect of the present invention, a film forming method forms a metal silicate film on a silicon substrate by metal organic CVD, and comprises a first step causing pre-reactions of a first vapor source including a metal alkoxide having a tertiary butoxyl group as a ligand and a second vapor source including a silicon alkoxide source, and generating a precursor used for a film formation, and a second step supplying the precursor onto the silicon substrate and forming the metal silicate film, so as to solve the problem described above.

According to a third aspect of the present invention, a recording medium is recorded with a program for causing a computer to carry out a film forming method in a film forming apparatus that comprises a processing chamber for holding therein a to-be-processed substrate, a first gas supplying means for supplying into the processing chamber a first vapor source including a metal alkoxide having tertiary butoxyl a group as a ligand, a second gas supplying means for supplying into the processing chamber a second vapor source including a silicon alkoxide source, and a pre-reaction means for causing pre-reactions of the first vapor source and the second vapor source, wherein the film forming method comprises a first step supplying the first vapor source and the second vapor source to the pre-reaction means and causing pre-reactions of the first vapor source and the second vapor source, and a second step supplying the first vapor source and the second vapor source after the pre-reactions into the processing chamber, so as to solve the problem described above.

### EFFECTS OF THE INVENTION

According to the present invention, it is possible to realize enable a film formation by MOCVD, with a satisfactory utilization efficiency of the source gas and a high productivity.

### BRIEF DESCRIPTION OF THE DRAWING

FIG. 1 is a diagram showing an example of a structure of a conventional film forming apparatus;

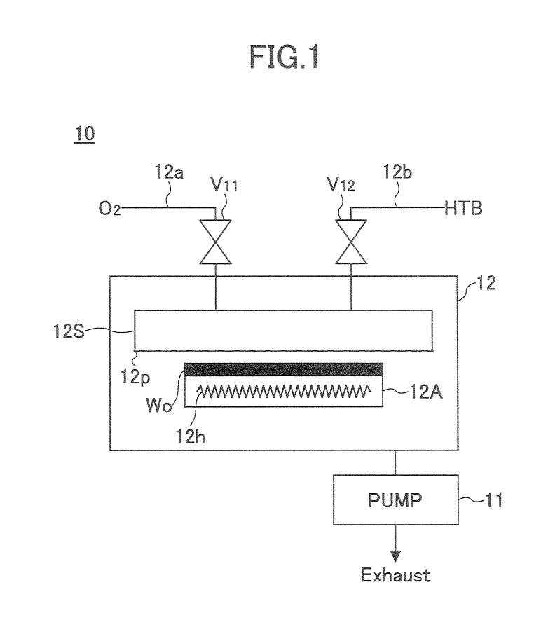

FIG. 2 is a diagram showing a thickness of a film formed by the film forming apparatus shown in FIG. 1;

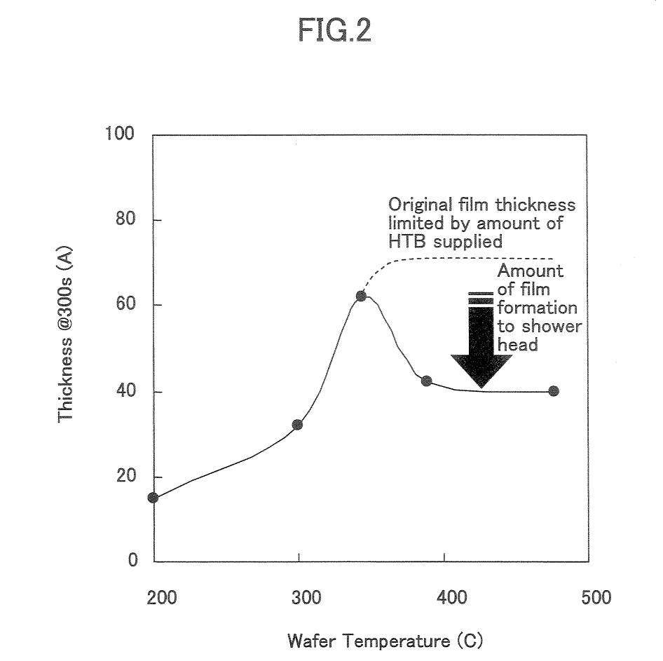

FIG. 3 is a diagram showing a structure of a film forming apparatus used for a film formation experiment;

FIG. 4 is a diagram showing a relationship of a deposition rate of a hafnium silicate film that is formed by the film forming apparatus shown in FIG. 3 and a TEOS flow rate;

FIG. 5 is a diagram showing a relationship of a refractive index of the hafnium silicate film that is obtained in FIG. 4 and the TEOS flow rate;

FIG. 6 is a diagram showing a relationship of the refractive index of the hafnium silicate film that is obtained in FIG. 4 and an Si concentration within the film;

FIG. 7 is a diagram showing a relationship of a virtual deposition rate of a SiO₂ component within the hafnium silicate film that is obtained in FIG. 4 and the TEOS flow rate;

FIG. 8 is a diagram showing a relationship of a virtual deposition rate of a HfO₂ component within the hafnium silicate film that is obtained in FIG. 4 and the TEOS flow rate;

FIG. 9 is a diagram showing a relationship of a deposition rate of the hafnium silicate film for a case where the TEOS flow rate is increased, the film composition and the TEOS flow rate;

FIG. 10 is a diagram showing a deposition reaction model of the hafnium silicate film;

FIG. 11A is a diagram showing an activation energy of HTB;

FIG. 11B is a diagram showing an activation energy of TEOS;

FIG. 12 is a diagram showing a structure of a film forming apparatus in an embodiment 1;

FIG. 13 is a diagram showing a film forming method of the embodiment 1;

FIG. 14 is a diagram showing a pre-reaction means used in the film forming apparatus shown in FIG. 12;

FIG. 15 is a diagram showing a thermal decomposition model of HTB;

FIG. 16 is a diagram showing an analysis result of FT-IR of HTB;

FIG. 17 is a diagram showing an analysis result of TG-DTA of HTB;

FIG. 18 is a diagram showing a preparatory mixing means of an embodiment 2;

FIG. 19 is a diagram showing a preparatory mixing means of an embodiment 3;

FIG. 20 is a diagram showing a preparatory mixing means of an embodiment 4;

FIG. 21 is a diagram showing a structure of the film forming apparatus of an embodiment 5;

FIG. 22A is a diagram (part 1) showing a thickness of a film that is deposited when a gap and an assist gas are changed;

FIG. 22B is a diagram (part 2) showing the thickness of the film that is deposited when the gap and the assist gas are changed;

FIG. 23 is a diagram showing a film thickness distribution of a HfO₂ film that is deposited on a to-be-processed substrate; and

FIG. 24 is a diagram showing optimum ranges for a gap size and a flow rate of the assist gas.

### DESCRIPTION OF THE REFERENCE NUMERALS

20, 30 MOCVD apparatus
21, 31 exhaust system
22, 32 processing chamber
22A, 32A substrate holding base
22h, 32h heating means
22a, 32a oxygen gas line
22f, 22d, 32f, 32d MFC
22b, 22c, 32b, 32c gas line
22e, 32e vaporizer
22S, 32S shower head
22P, 32P opening
23A, 23B, 32A, 32B source container
41 reaction tube
41A processing space
42 heating means
44 substrate holding structure
45 exhausting means
100, 150, 200, 300 pre-reaction means
102 pressure adjusting means
100a reaction chamber
100A, 200A reaction space
100b, 150b, 300A heating means
300a, 300b, 300c, 300d, 300e heater

### BEST MODE OF CARRYING OUT THE INVENTION

Next, a description will be given of the concept of the present invention.

For example, within a processing chamber that holds therein a to-be-processed substrate in a film forming apparatus that forms a high-K dielectric film, a source gas that becomes the source of the high-K dielectric film is decomposed at portions other than on the to-be-processed substrate, and a film may be formed at such portions. For this reason, there were problems in that, the required maintenance intervals of the film forming apparatus becomes short, the film that is formed at the portions other than on the to-be-processed substrate within the processing chamber may separate and generate particles that become the contamination source with respect to the to-be-processed substrate, and the amount of the source gas that is expensive increases.

In order to eliminate such problems, the film forming apparatus of the present invention, that forms a high-K dielectric film by MOCVD, is configured as follows. For example, a pre-reaction means is provided for causing a pre-reaction of a first vapor source including a metal alkoxide having a tertiary butoxyl group as a ligand, and a second vapor source including a silicon alkoxide source, and the first vapor source and the second vapor source after the pre-reactions are supplied into a processing chamber, so as to form a film on a to-be-processed substrate.

By configuring the apparatus in this manner, it is possible to obtain the effect of suppressing the formation of a film of the first vapor source at locations other than on the to-be-processed substrate before reaching the to-be-processed substrate.

In this case, because the pre-reaction means is provided for causing the pre-reactions of the first vapor source including the metal alkoxide having a tertiary butoxyl group as the ligand, such as hafnium tetratertiary butoxyl (HTB), and the second vapor source including the silicon alkoxide source, such as tetra ethyl ortho silicate (TEOS), the second vapor source reacts to a first precursor that is active and is generated by the decomposition of the first vapor source. Consequently, a second precursor, that is relatively inactive with respect to the first precursor, is generated by the pre-reaction means.

For this reason, the second precursor that is relatively inactive is mainly supplied into the processing chamber, and the second precursor mainly contributes to the firm formation. Accordingly, it is possible to suppress the film formation at locations other than on the to-be-processed substrate within the processing chamber.

In addition, by adding the second vapor source to the first vapor source, the film that is formed includes Si (for example, a hafnium silicate film), and such a silicate material has a lower dielectric constant but the crystallization of the film is unlikely to occur compared to oxide materials. Hence, such a silicate material is suited for use as a high-K gate insulator film of a semiconductor device.

The present inventors have found the reasons why the above described effect is obtained by configuring the apparatus in the manner described above, through following experiment that was conducted. Next, a detailed description will be given of the experiment and the analysis result of the results obtained by the experiment.

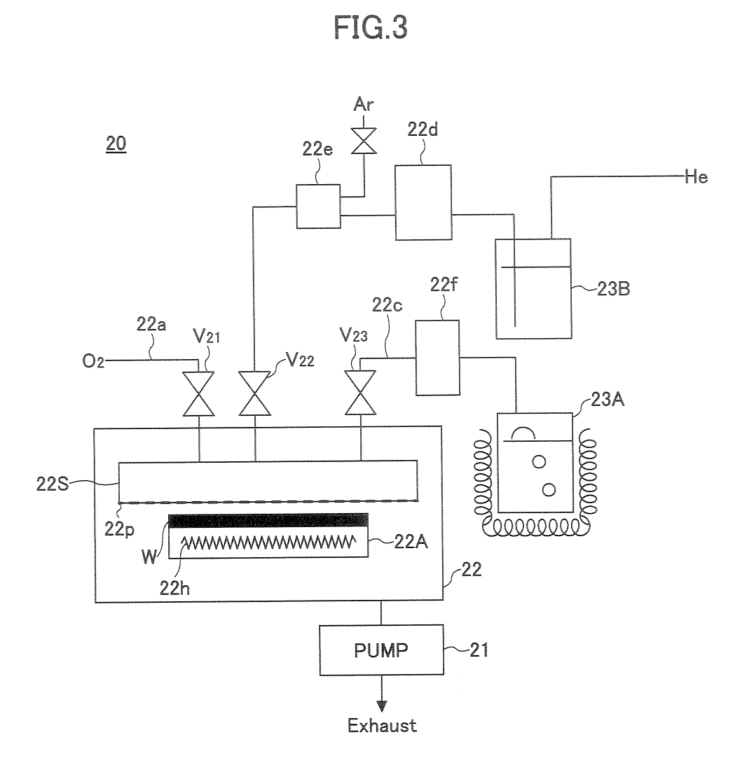

FIG. 3 shows a structure of a film forming apparatus 20 that is the MOCVD apparatus used for the experiment.

The MOCVD apparatus 20 shown in FIG. 3 has a processing chamber 22 that is exhausted by a pump 21. A to-be-processed substrate W is held within the processing chamber 22 by a holding base 22A that has a heating means 22h embedded therein.

A shower head 22S is also provided within the processing chamber 22 so as to confront the to-be-processed substrate W. A line 22a for supplying oxygen gas is connected to the shower head 22S via an MFC (Mass Flow Controller) which is not shown and a valve V21.

The MOCVD apparatus 20 has a container 23B for holding a first source including a metal alkoxide having a tertiary butoxyl group as a ligand, such as HTB. The first source within the container 23B is supplied to a vaporizer 22e via a fluid flow rate controller 22d by a pumping gas, such as He gas, and the first source that is vaporized by the vaporizer 22e with the help of a carrier gas, such as Ar gas, is supplied, as the first source gas, to the shower head 22S via a valve V22.

The film forming apparatus 20 has a heating container 23A for holding a second source including a silicon alkoxide source, such as TEOS. The second source that is vaporized by the heating container 23A is supplied, as the second source gas, to the shower head 22S via an MFC 22f and a valve V23.

The oxygen gas, the first source gas (HTB gas) and the second source gas (TEOS gas) pass through respective passages within the shower head 22S, and are ejected to a processing space within the processing chamber 22 via openings 22p that are formed in a surface of the shower head 22S confronting the silicon substrate W.

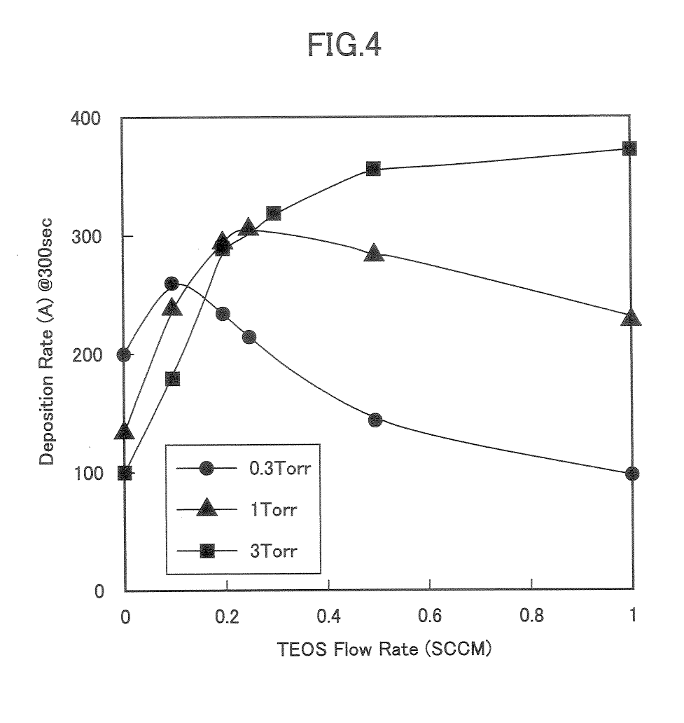

FIG. 4 shows the results that are obtained for the deposition rate of the Hf silicate film that is formed on the silicon substrate W in a case where the substrate temperature within the film forming apparatus 20 shown in FIG. 3 is set to 550° C., the HTB gas is supplied at a flow rate of 0.33 SCCM, the oxygen gas is supplied at a flow rate of 300 SCCM and the flow rate of the TEOS gas is gradually increased from 0 (zero), when the processing pressure within the processing chamber 22 is set to 40 Pa (0.3 Torr), 133 Pa (1 Torr) and 399 Pa (3 Torr). In FIG. 4, the deposition rate of the Hf silicate film is represented by the film thickness that is measured after the deposition is made for 300 seconds.

As shown in FIG. 4, a HfO₂ film that includes no Si is deposited on the silicon substrate W when the TEOS flow rate is 0 SCCM, but when the TEOS flow rate increases, the Si concentration included within the HfO₂ film increases, such that the film composition becomes Hf silicate.

In this state, if the processing pressure is set to 399 Pa (3 Torr), the deposition rate increases with increasing TEOS flow rate as shown in FIG. 4. But when the processing pressure is set to 133 Pa (1 Torr) or 40 Pa (0.3 Torr), it may be seen that the deposition rate first increases with increasing TEOS flow rate and thereafter begins to decrease.

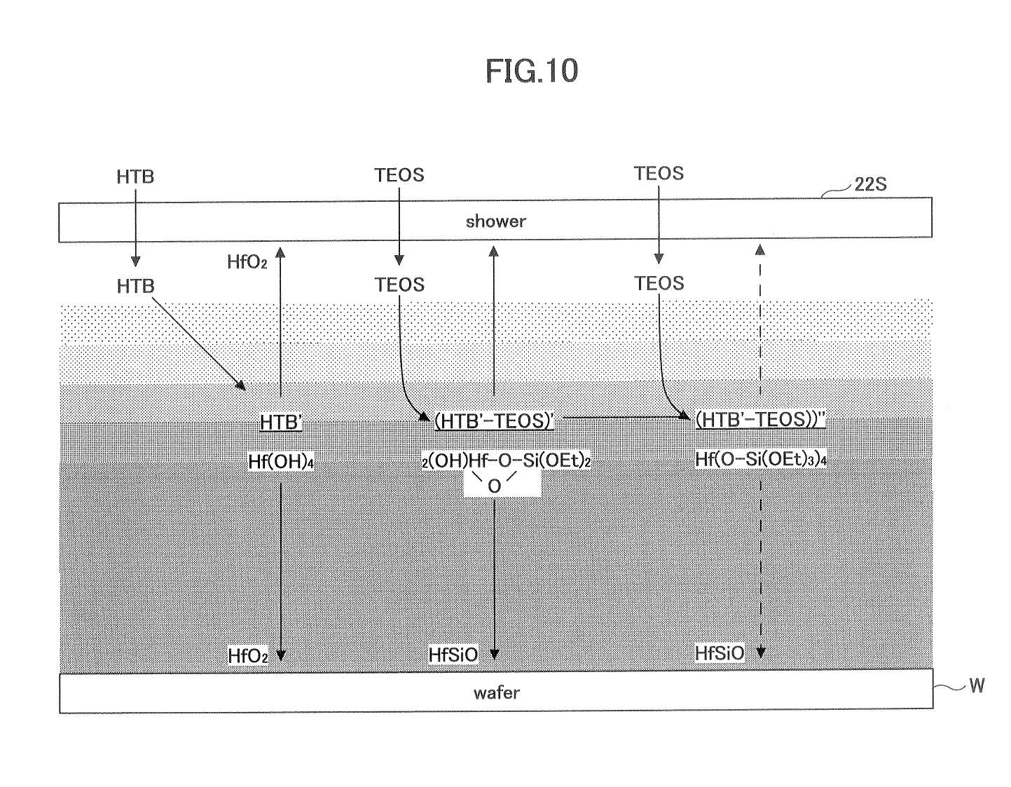

It may be regarded that the following two effects are generally responsible for this tendency of the deposition rate. According to the first effect, it may be regarded that the proportion of the precursor that contributes to the film formation and is consumed (forms a film) at the location other than the to-be-processed substrate, such as at the shower head, changes depending on the film forming conditions. According to the second effect, it may be regarded that, of the precursors that contribute to the film formation, the proportion with which the active precursor and the inactive precursor are generated changes depending on the film forming conditions. The details of these effects will be described later in conjunction with FIG. 10 using a film formation model.

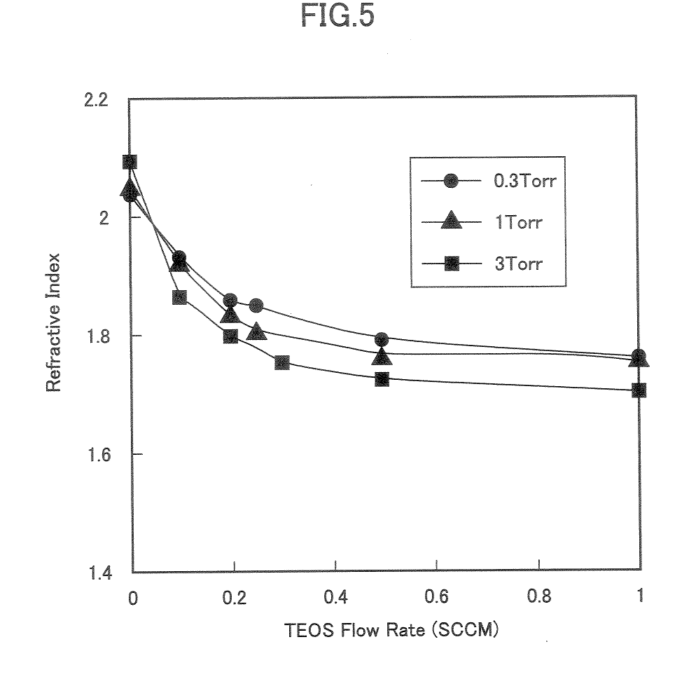

FIG. 5 is a diagram showing a refractive index of the Hf silicate film that is obtained in this manner as a function of the TEOS flow rate.

As shown in FIG. 5, the film that is obtained has a refractive index of 2.05 to 2.1 when the TEOS flow rate is 0 SCCM, and the refractive index satisfactorily matches the refractive index value of the HfO₂. For this reason, it may be regarded that film that is formed by setting the TEOS flow rate to 0 SCCM is actually a HfO₂ film.

On the other hand, when the film is formed by adding the TEOS to the source gas, the refractive index falls to approximately 1.8, but considering the fact that the refractive index of a SiO₂ film is approximately 1.4, it may be regarded that the film that is actually formed by adding the TEOS to the source gas is actually a hafnium silicate film.

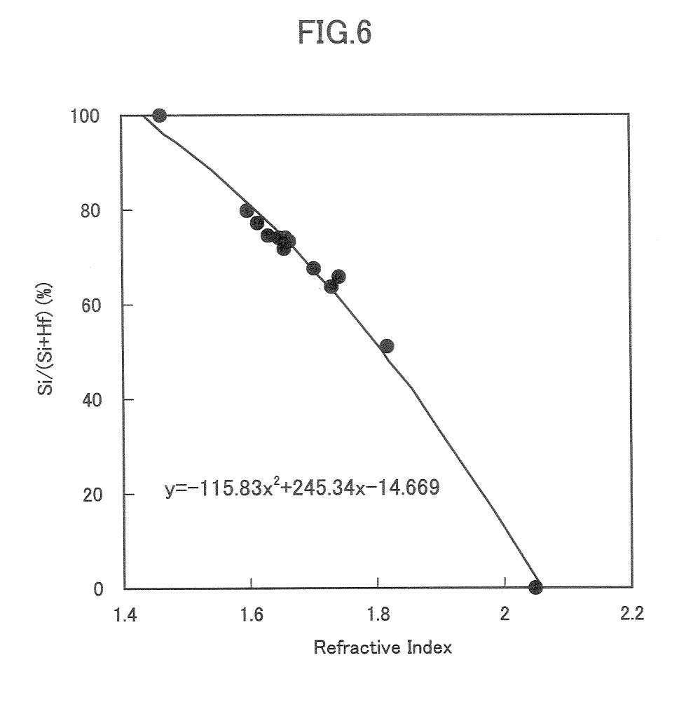

FIG. 6 shows a relationship of a Si concentration (Si/Si+Hf)) within the hafnium silicate film that is obtained and the refractive index. In FIG. 6, the Si concentration is indicated by the atomic % of Si. In the present invention, the Si concentration and the Hf concentration are measured by the XPS.

As may be seen from FIG. 6, a clear corresponding relationship exists between the Si concentration within the film and the refractive index. Hence, in the relationship shown in FIG. 5 described above, it may be seen that the Si concentration within the hafnium silicate film that is obtained changes together with the TEOS flow rate.

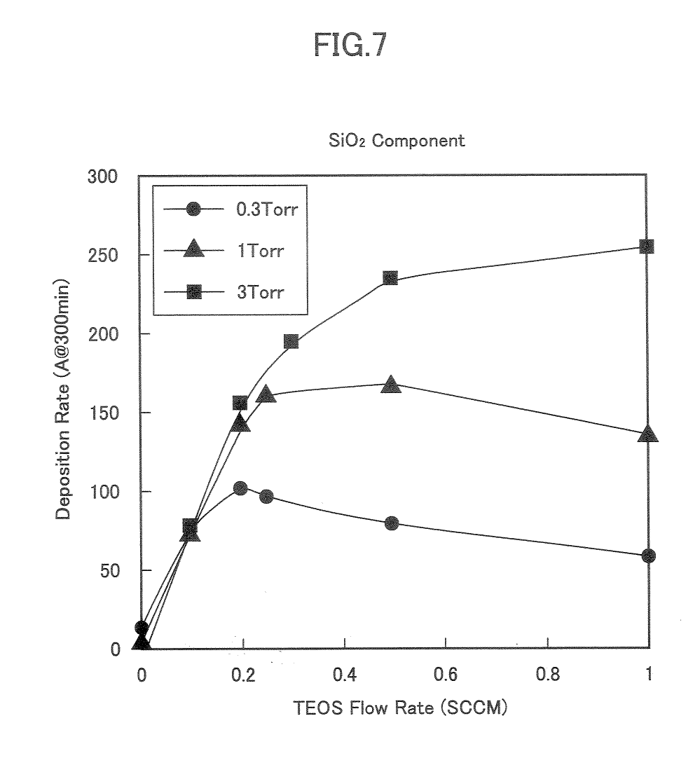

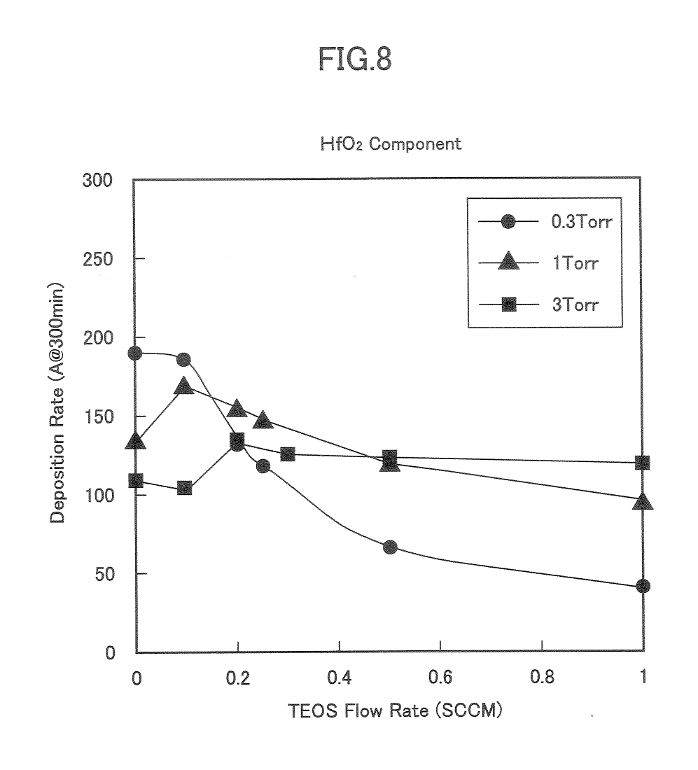

FIG. 7 shows the results that are obtained by calculating a virtual deposition rate of a SiO₂ component within the hafnium silicate film using a specific volume of SiO₂, based on a proportion of the SiO₂ component that is included within the hafnium silicate film and is calculated from the relationship shown in FIG. 4 using the relationships shown in FIGS. 5 and 6. Similarly, FIG. 8 shows the results that are obtained by calculating a virtual deposition rate of a HfO₂ component within the hafnium silicate film using a specific volume of HfO₂, based on a proportion of the HfO₂ component that is included within the hafnium silicate film and is calculated from the relationships shown in FIGS. 4, 5 and 6.

As may be seen from FIGS. 7 and 8, in the case where the processing pressure is 40 Pa (0.3 Torr), the deposition rate of the HfO₂ component rapidly decreases when the SiO₂ component is introduced into the film by the supply of the TEOS. A similar decrease in the HfO₂ component also occurs in the case where the processing pressure is 133 Pa (1 Torr), but it may be seen that such a decrease in the HfO₂ does not occur in the case where the processing pressure is 399 Pa (3 Torr). The phenomena shown in FIGS. 7 and 8 suggest that, when the hafnium silicate film is deposited, the TEOS introduced into the processing chamber 22 has a function of prohibiting the deposition of the Hf atoms.

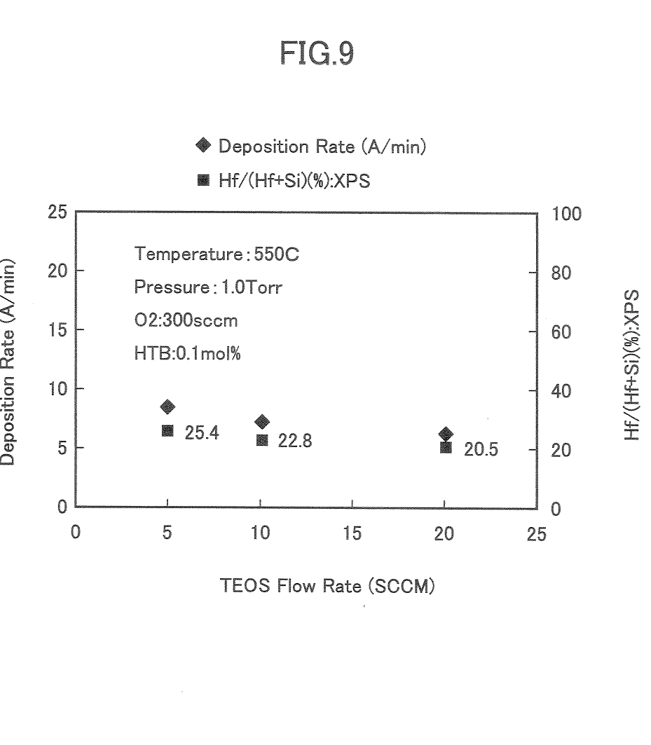

FIG. 9 shows a deposition rate (left ordinate) of the hafnium silicate film and a Hf concentration (right ordinate) within the film, for the case where the TEOS flow rate is further increased and changed in a range of 5 SCCM to 20 SCCM.

As may be seen from FIG. 9, the deposition rate of the film slightly decreases with increasing TEOS flow rate, and the Hf concentration within the film makes a corresponding convergence to 20 atomic %, that is, the ratio of the Hf atoms and the Si atoms converges to 1:4. In FIG. 9, the substrate temperature is set to 550° C., the oxygen gas is supplied into the processing chamber 22 at a flow rate of 300 SCCM, and the HTB is introduced at a proportion of 0.1 mol % with respect to the TEOS.

FIG. 10 shows a model of the MOCVD process that is carried out within the film forming apparatus shown in FIG. 3 when the matters described above are taken into consideration.

As shown in FIG. 10, when the HTB is introducing to the processing space within the processing chamber 22 via the shower head 22S, a desorption of a ligand (CH₃)₃C occurs, and an extremely active precursor Hf(OH)₄ (hereinafter simply referred to as HTB′) is formed. When this HTB′ is conveyed to the surface of the substrate W or the surface of the shower head, the desorption of H₂O occurs due to the surface reaction, to thereby cause a deposition of HfO₂ The H₂O and the (CH₃)₃C, both caused by the desorption, bond to each other and are exhausted outside the processing chamber 22 in the form of (CH₃)₃C—OH.

On the other hand, when the TEOS is introduced into the low-pressure system in which this reaction occurs, a portion of the active HTB′ and the TEOS bond as shown in FIG. 10, and a precursor (HTB′-TEOS)′ described by a reaction formula (A) is formed.

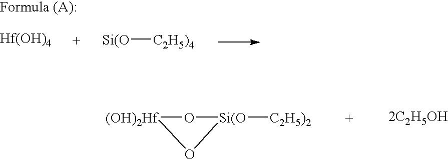

When this precursor (HTB′-TEOS)′ is conveyed to the surface of the silicon substrate W, a hafnium silicate (hereinafter referred to as HfSiO) film rich in Hf is deposited.

Therefore, in the low-pressure reaction, the deposition reaction of the (HTB′-TEOS)′ and the deposition reaction of the HfO₂ film due to the HTB′ are in conflict with each other. It may be regarded that, when the TEOS is introduced, the deposition reaction of HfO₂ is rapidly suppressed, and the rapid decrease in the deposition rate of the HfO₂ component described above in conjunction with FIGS. 7 and 8 occurs.

On the other hand, when the flow rate of the TEOS supplied to the shower head 22S further increases, another precursor (HTB′-(TEOS))″ described by a reaction formula (B) is formed, in which the TEOS is further bonded to the precursor (HTB′-TEOS)′.

Hf(OH)₄+4Si(O—C₂H₅)₄→Hf[—O—Si(O—C₂H₅)₃]₄+4C₂H₅OH

When this precursor (HTB′-(TEOS))″ is conveyed to the surface of the silicon substrate W, a hafnium silicate (hereinafter referred to as HfSiO) rich in Si is deposited. The reaction related to the precursor (HTB′-(TEOS))″ is the reaction that becomes dominant in the normal MOCVD exceeding 133 Pa (1 Torr).

This other precursor (HTB′-(TEOS))″ has a structure in which four Si atoms are bonded to one Hf atom via respective oxygen atoms. In the hafnium silicate film that is formed by the reaction involving such a precursor, there is a tendency of the ratio of the Hf atoms and the Si atoms within the film to become 1:4 as shown in FIG. 9.

Therefore, it may be regarded that, when the TEOS is added to the HTB, a reaction that changes the precursor contributing to the film formation occurs. Hence, by positively utilizing this phenomenon, and configuring the film forming apparatus so that a desired precursor occupies a large proportion of the precursors that are within the processing chamber and contribute to the film formation, it becomes possible to suppress the amount of film formation occurring at locations other than on the to-be-processed substrate within the film forming apparatus, such as the shower head.

For example, if the TEOS is added to the HTB, the precursor (HTB′-TEOS)′ that may be regarded inactive with respect to the active precursor HTB′ is generated when the processing pressure is 1 Torr or lower, and the precursor (HTB′-(TEOS))″ that may be regarded inactive with respect to the active precursor HTB′ is generated when the processing pressure is 399 PA (3 Torr) or higher, and it may be regarded that such precursors mainly contribute to the film formation.

It may be regarded that the change in the deposition rate due to the film forming conditions shown in FIG. 4 can be explained satisfactorily by the film formation model.

In the case shown in FIG. 4, it may be regarded that the deposition rate corresponds to the number of precursors that reach the to-be-processed substrate and contribute to the film formation, and the increase or decrease in the deposition rate corresponds to the change in the number of precursors reaching the to-be-processed substrate.

For example, if the processing pressure is 133 Pa (1 Torr) or lower, the deposition rate increases as the flow rate of the TEOS increases from 0 SCCM, and there is a maximum value. But in a region where the flow rate of the TEOS is greater than or equal to a predetermined flow rate, the deposition rate again decreases.

It may be regarded that this region where the deposition rate decreases is due to the increase in the proportion of the precursor (HTB′-TEOS)′ that is generated by the bonding of the TEOS to the precursor HTB′ within the processing chamber, with respect to the precursor HTB′, as the flow rate of the TEOS increases.

It may be regarded that, as the flow rate of the TEOS increases from 0 SCCM, the proportion of the active precursor HTB′ which is believed to form a film before reaching the to-be-processed substrate, such as at the shower head, decreases, the proportion of the precursor (HTB′-TEOS)′ reaching the to-be-processed substrate increases, and the deposition rate increases. However, the deposition rate takes the maximum value as the flow rate of the TEOS increases, and thereafter decreases as the flow rate of the TEOS is further increased. It may be regarded that this is caused by the increase in the proportion of the precursor that is exhausted from within the processing chamber without contributing to the film formation as the proportion of the precursor (HTB′-TEOS)′ further increases.

On the other hand, if the processing pressure is 399 Pa (3 Torr) or higher, it may be regarded that the probability of collision of the HTB molecules and the TEOS molecules is large, and the bonding of the TEOS molecules with respect to the precursor HTB′ quickly saturates even when the flow rate of the TEOS is approximately 0.5 SCCM. Hence, it may be regarded that, of the precursors that contribute to the film formation, the precursor (HTB′-(TEOS))″ becomes the dominant, and the effect of increasing the deposition rate with increasing flow rate of the TEOS saturates when the flow rate of the TEOS is approximately 0.5 SCCM.

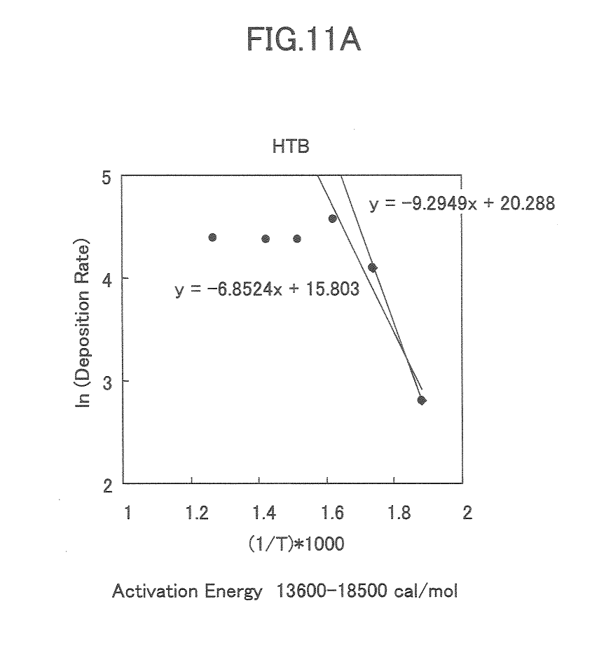

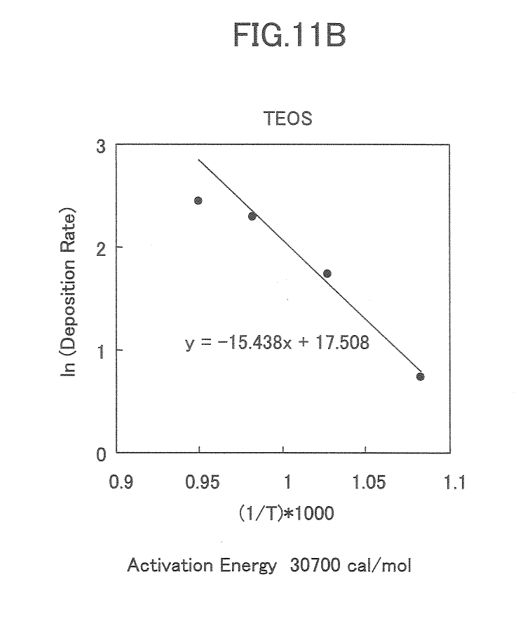

FIGS. 11A and 11B show activation energies of the HTB and the TEOS. As shown in FIGS. 11A and 11B, the activation energy of the HTB is 13600 cal/mol to 18500 cal/mol, while the activation energy of the TEOS is 30700 cal/mol. In other words, it may be seen that compared to the HTB, the TEOS requires a large energy for activation (refer to S. Rojas, J. Vac. Sci. Technol. B81177 (1990)).

Accordingly, it may easily be analogized that compared to the activation energy of the precursor HTB′, the activation energies of the precursors (HTB′-TEOS)′ and the precursor (HTB′-(TEOS))″ that have a structure in which the TEOS is bonded to the precursor HTB′ are large. In other words, it is clear that compared to the precursor HTB′, the precursors (HTB′-TEOS)′ and the precursor (HTB′-(TEOS))″ are more inactive (or, the precursor HTB′ is more active than the precursors (HTB′-TEOS)′ and the precursor (HTB′-(TEOS))″).

The film forming apparatus of the present invention is characterized in that the apparatus is configured to generate an inactive precursor from an active precursor, so as to suppress the film formation at locations other than on the to-be-processed substrate or, so as to improve the utilization efficiency of the source gas. For example, the film forming apparatus of the present invention has a pre-reaction means for causing pre-reactions of a first vapor source including a metal alkoxide having a tertiary butoxyl group as a ligand, such as the HTB, and a second vapor source including a silicon alkoxide source, such as the TEOS.

Next, a description will be given of the configuration of the film forming apparatus having such characteristics.

### Embodiment 1

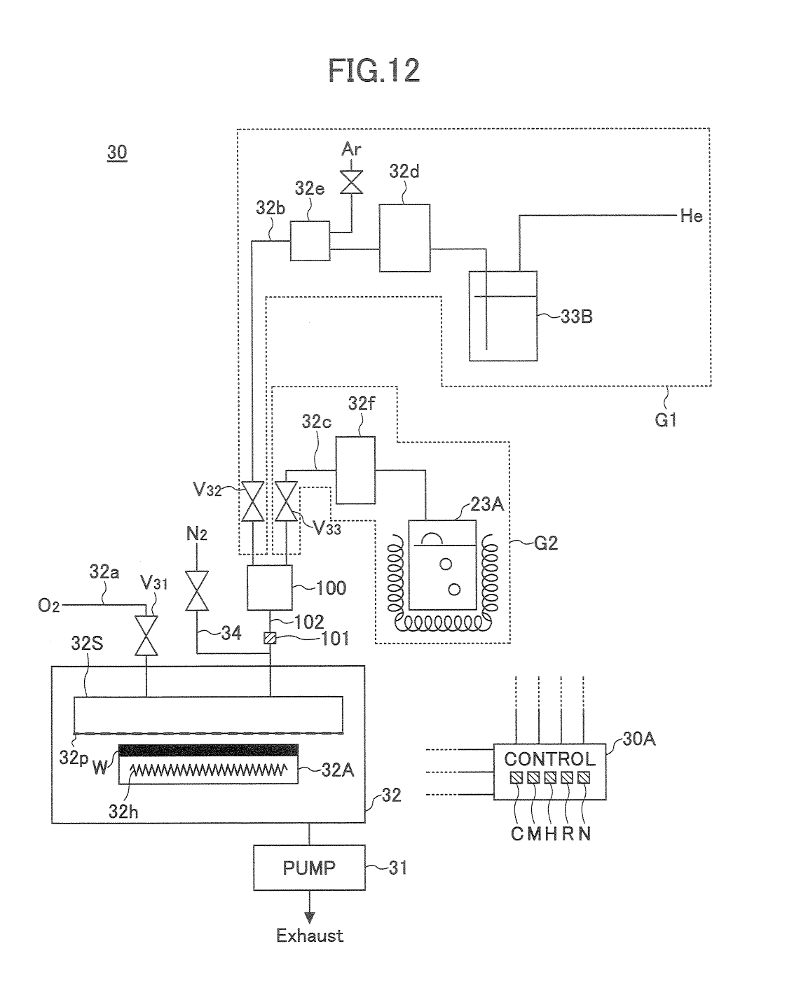

FIG. 12 is a diagram schematically showing a film forming apparatus 30 in an embodiment 1 of the present invention.

As shown in FIG. 12, the film forming apparatus 30 has a processing chamber 32 that is exhausted by a pump 31. A to-be-processed substrate W made of silicon, for example, is held within the processing chamber 32 by a holding base 32A that has a heating means 32h embedded therein.

A shower head 32S is also provided within the processing chamber 32 so as to confront the to-be-processed substrate W. A line 32a for supplying oxygen gas is connected to the shower head 32S via an MFC (Mass Flow Controller) which is not shown and a valve V31.

The film forming apparatus 30 of this embodiment further has a first gas supplying means G1, within the processing chamber 32, for supplying a first vapor source including a metal alkoxide (for example, HTB) having a tertiary butoxyl group as a ligand, and a second gas supplying means G2, within the processing chamber 32, for supplying a second vapor source including a silicon alkoxide source (for example, TEOS).

The first gas supplying means G1 and the second gas supplying means G2 are connected to a pre-reaction means 100 for causing pre-reactions of the first vapor source and the second vapor source. The first vapor source and the second vapor source after the pre-reactions caused by the pre-reaction means 100 are supplied from the pre-reaction means 100 to the shower head 32S via a supply line 102.

In addition, a gas line 34 for supplying to the shower head 32S a gas (hereinafter referred to as an assist gas), such as N₂ gas, for diluting the first vapor source or the second vapor source, is connected to the supply line 102.

The oxygen gas, the first vapor source (HTB gas) and the second vapor source (TEOS gas) pass through respective passages within the shower head 32S, and are ejected to a processing space within the processing chamber 32 via openings 32P that are formed in a surface of the shower head 32S confronting the to-be-processed substrate W.

The first gas supplying means G1 has a container 33B for holding a first source including a metal alkoxide having a tertiary butoxyl group as a ligand, such as HTB. The first source within the container 33B is supplied to a vaporizer 32e via a fluid flow rate controller 32d, and the first source that is vaporized by the vaporizer 32e with the help of a carrier gas, such as Ar gas, is supplied, as the first vapor source, to the pre-reaction means 100 by a gas line 32b via a valve V32.

The second gas supplying means G2 has a heating container 33A for holding a second source including a silicon alkoxide source, such as TEOS. The second source that is vaporized by the heating container 33A is supplied, as the second vapor source, to the pre-reaction means 100 by a gas line 32c via an MFC 32f and a valve V33.

The film forming apparatus 30 of this embodiment is configured so that the pre-reaction means 100 causes the pre-reactions of the HTB and the TEOS, so as to generate the inactive precursor (HTB′-TEOS)′ or the inactive precursor (HTB′-(TEOS))″ from the active precursor HTB′, and such inactive precursors (having a large activation energy) are supplied to the processing chamber 32, so as to form a film. For this reason, the amount of film that is formed at portions other than on the to-be-processed substrate W that is heated by the heating means 32h, such as the shower head 32S, is suppressed, and it is possible to efficiently convey the precursors to the to-be-processed substrate.

Accordingly, it is possible to obtain the effect of suppressing the amount of film that is formed within the processing chamber at locations other than on the to-be-processed substrate. Consequently, it is possible to suppress the generation of particles that occurs when the film formed within the processing chamber separates, for example, and it is possible to form the film in a clean environment. In addition, by suppressing the film formation within the processing chamber, it is possible to reduce the maintenance intervals of the apparatus and to improve the rate of operation of the apparatus, so as to efficiently form the film. Moreover, since the utilization efficiency of the sources improves, it is possible to suppress the amount of sources consumed, and to reduce the cost of forming the film.

In a case where there is only provided a structure that joins (or joins within the shower head) the pipe that supplies the first vapor source and the pipe that supplies the second vapor source, such that the first vapor source and the second vapor source are certainly mixed, so as to cause the pre-reaction described above, it may be difficult to cause a sufficient pre-reaction described by the reaction formula (A) or the reaction formula (B). For this reason, it is preferable to provide the pre-reaction means separately from the conventional pipes and the processing chamber.

The film forming apparatus 30 of this embodiment has a control means 30A, having a built-in computer, for controlling the operation of the film forming apparatus 30 related to the substrate processing, such as the film formation. The control means 30A has a recording medium that stores the film forming method, such as a program for causing the computer to operate the film forming apparatus according to the film forming method. The computer operates the film forming apparatus based on the program.

For example, the control unit 30A has a CPU (computer) C, a memory M, a storage medium H such as a hard disk, a removable storage medium R, a network connection means N, and a bus that is not shown and connects these elements of the control unit 30A. This bus is also connected to the valves, the exhaust means, the mass flow rate controller, the heating means and the like of the film forming apparatus described above. The storage medium H is recorded with the program for operating the film forming apparatus, and this program is sometimes referred to as a recipe. This program may be input to the control means via the storage medium R or the network connection means N. For example, the following example of the film forming method is realized by controlling the film forming apparatus based on the program that is stored in the control means.

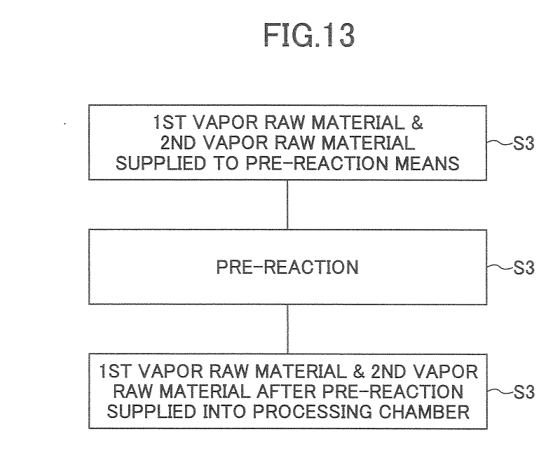

FIG. 13 is a flow chart showing an example of the film forming method carried out by the film forming apparatus 30 described above. First, in a step 1 (indicated as S1 in FIG. 13, and similarly for other steps), the first vapor source from the first gas supplying means G1 and the second vapor source from the second gas supplying means G2 are supplied to the pre-reaction means 100.

In a step 2, the pre-reactions of the first vapor source and the second vapor source take place in the pre-reaction means 100, and the reaction described by the reaction formula (A) or the reaction formula (B) occurs to thereby generate the precursor that is used for the film formation.

Next, in a step 3, the first vapor source and the second vapor source after the pre-reaction, including the precursor, are supplied into the processing chamber 32 from the supply line 102, and a metal silicate film (for example, hafnium silicate film) is formed on the to-be-processed substrate W that is made of silicon.

In the step 2, it is preferable that the first vapor source and the second vapor source are heated, but a detailed description thereof will be given later.

Next, a description will be given of an example of the structure of the pre-reaction means 100 that is used in the film forming apparatus 30.

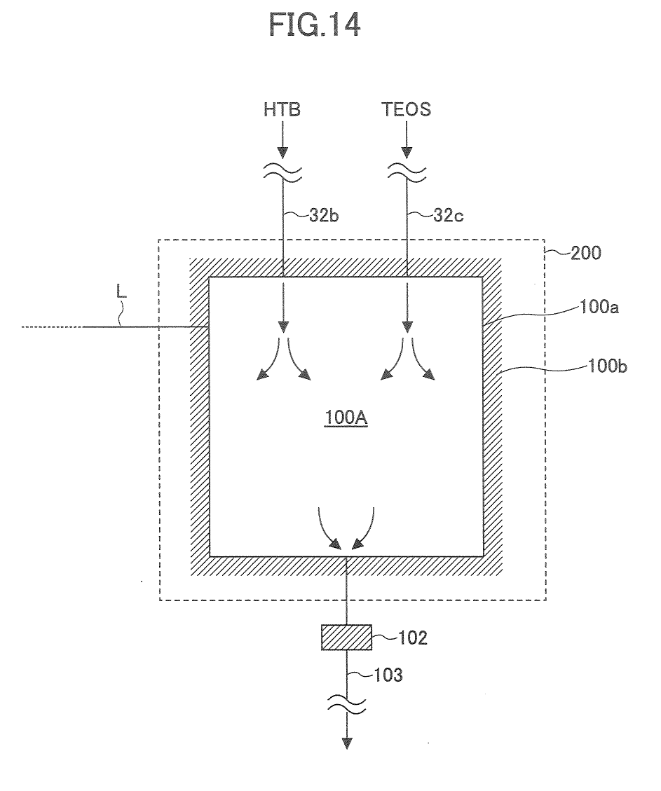

FIG. 14 is a diagram schematically showing a cross section of the pre-reaction means 100, which is an example of a pre-reaction means of the present invention. In FIG. 14, those parts that are the same as those corresponding parts in the preceding figures are designated by the same reference numerals, and a description thereof will be omitted.

As shown in FIG. 14, the pre-reaction means 100 has a reaction chamber 100a having an approximate cylindrical shape. The gas lines 32b and 32c are connected to a first side of the cylindrical shape, so that the first vapor source and the second vapor source are supplied to a reaction space 100A within the reaction chamber 100a The first vapor source and the second vapor source that are supplied in this manner are mixed within the reaction space 100A, and the precursor (HTB′-TEOS)′ or the precursor (HTB′-(TEOS))″ are generated by the reaction described by the reaction formula (A) or the reaction formula (B). When causing the pre-reaction, it is not essential for all of the HTB and TEOS to be making the reaction, and the reaction only needs to be such that, of the vapor sources (pre-reaction vapor sources) after the pre-reaction, the proportion occupied by the precursor (HTB′-TEOS)′ or the precursor (HTB′-(TEOS))″ increases.

A pressure adjusting means 102 is provided on the supply line 103 that is connected to the second side opposite to the first side of the pre-reaction means 100. The pressure adjusting means 102 adjusts the pressures of the first vapor source and the second vapor source that are caused to make the pre-reaction in the pre-reaction means 100. From the point of view of promoting the reaction, it is preferable to increase the pressure within the reaction space 100A when causing the pre-reaction.

For example, the pressure adjusting means 102 includes a conductance adjusting means that is provided on the supply line 103 which is a supply passage through which the first vapor source and the second vapor source after the pre-reaction are supplied into the processing chamber. For example, the conductance adjusting means may be formed by orifices having conductances fixed thereon or, a conductance adjusting means having a variable conductance.

The pre-reaction means 100 preferably has a heating means for heating the first vapor source and the second vapor source that are supplied to the pre-reaction means 100, because it is possible to promote the pre-reaction by the heating.

For example, in the case of the pre-reaction means 100 of this embodiment, a heating means 100b formed by a heater, for example, is provided so as to cover the reaction chamber 100a. In addition, the heating means 100b is connected to the control unit 30A shown in FIG. 12 via a connecting means L to control the amount of heating so that the first vapor source and the second vapor source within the reaction chamber 10a have a desired temperature.

The desired temperature is the temperature at which the reaction described by the reaction formula (A) or the reaction formula (B) occurs. In this case, the desired temperature is preferably set to the temperature that enables decomposition of the HTB.

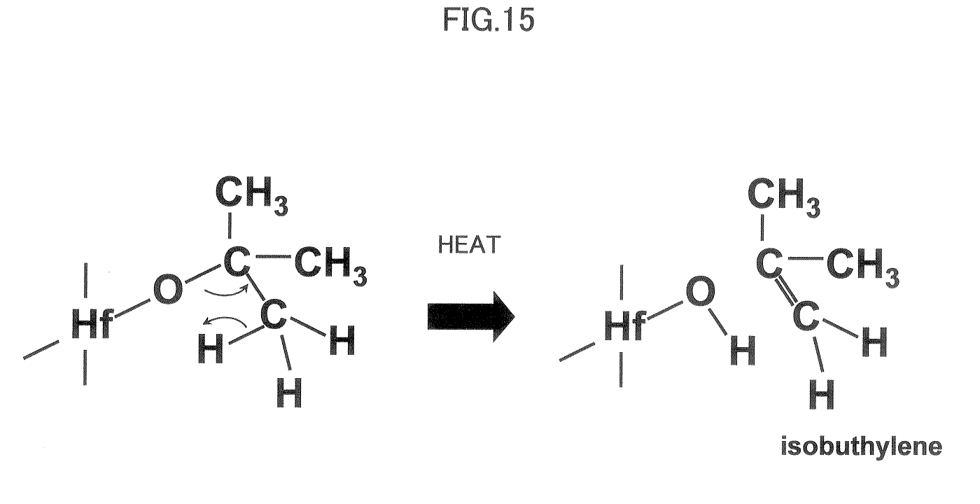

FIG. 15 schematically shows the state where the HTB is heated and the decomposition of the HTB begins. As shown in FIG. 15, when the HTB is heated, it is known that isobutylene is generated by the decomposition of the HTB.

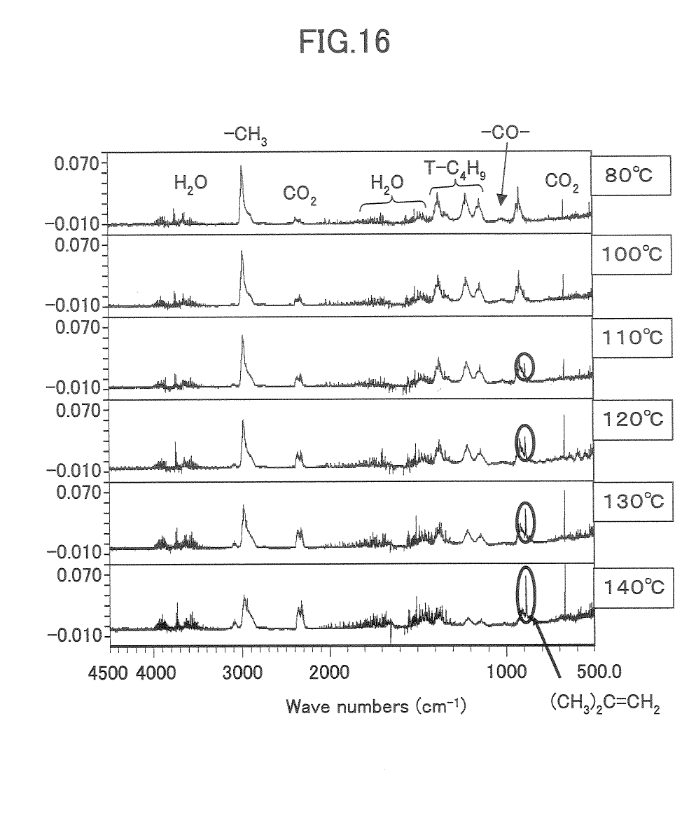

FIG. 16 shows the decomposition spectrum of the HTB by FT-IR (infrared absorption spectroscopy) for cases where the heating temperature is 80° C., 100° C., 110° C., 120° C., 130° C. and 140° C. As shown in FIG. 16, when the heating temperature is 80° C. to 100° C., no peak of the isobutylene is observed in the spectrum. However, when the heating temperature is 110° C., a peak of the isobutylene is observed in the spectrum, and the decomposition of the HTB can be confirmed. For this reason, the temperature to which the first vapor source and the second vapor source are heated by the heating means 100b is preferably set to 110° C. or higher.

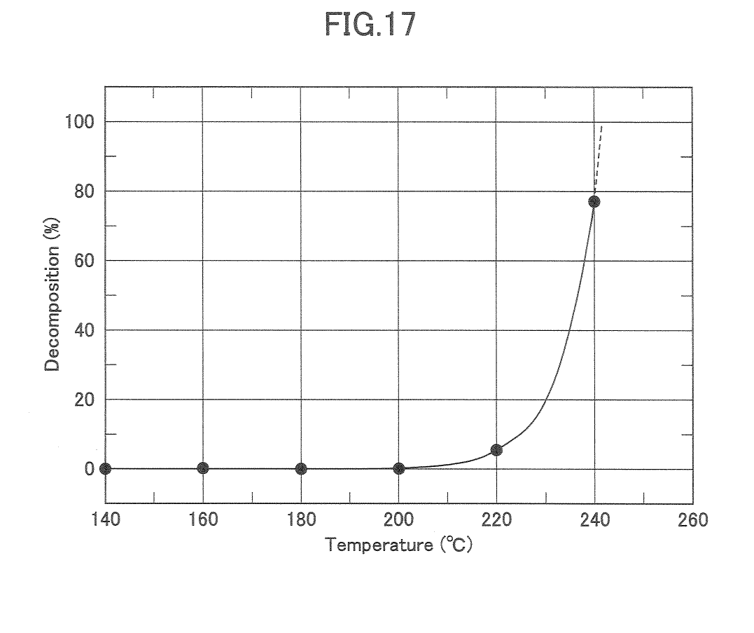

FIG. 17 shows the results obtained by TG-DTA (Differential Thermal Analysis) of the HTB. As shown in FIG. 17, the HTB decomposition progresses with increasing HTB temperature, and it may be seen that approximately 80% of the HTB is decomposed at a temperature of 240° C. In addition, from the slope of the graph, it may be anticipated that the HTB will virtually be decomposed in its entirety when the HTB temperature is 250° C., and it may be regarded that a further increase in the HTB temperature will not affect the HTB decomposition.

Accordingly, it may be seen that it will be sufficient if the temperature to which the first vapor source and the second vapor source are heated by the heating means 100b is set to 250° C. or lower.

### Embodiment 2

In the film forming apparatus 30 described above, the pre-reaction means is not limited to the structure of the embodiment 1 described above, and various variations and modifications may be made, as described below.

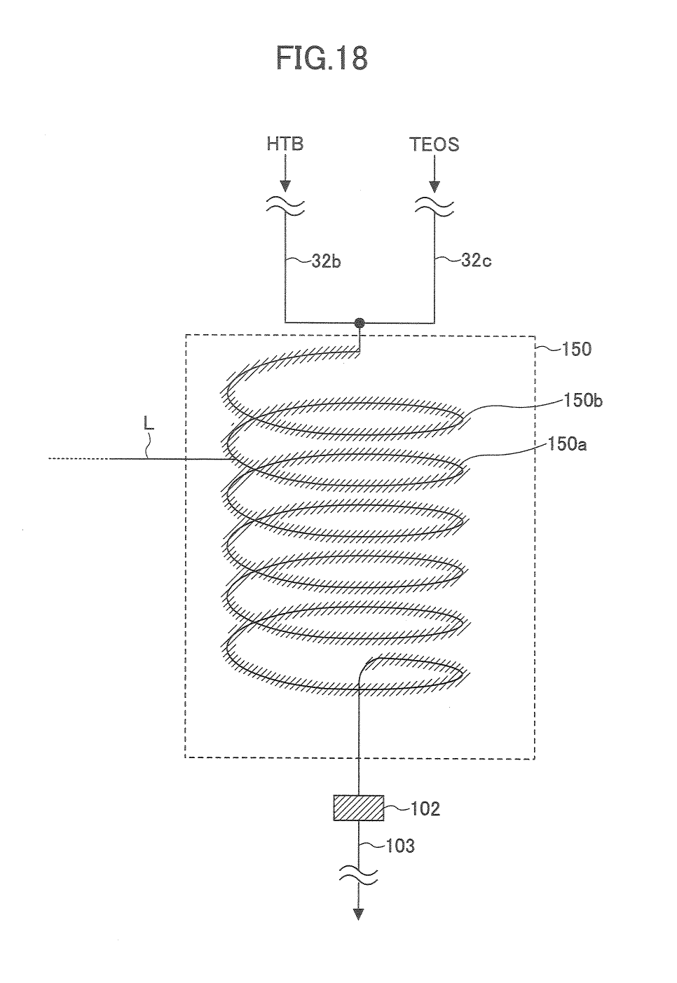

For example, FIG. 18 is a diagram schematically showing a cross section of a pre-reaction means 150 in the embodiment 2 of the present invention. In FIG. 18, those parts that are the same as those of the preceding figures are designated by the same reference numerals, and a description thereof will be omitted.

As shown in FIG. 18, the pre-reaction means 150 of this embodiment has a spiral pipe 150a in which the first vapor source and the second vapor source are mixed. The gas lines 32b and 32c are connected to one end of the pipe 150a, and the supply line 103 is connected to the other end of the pipe 150a. Since the pipe 150a has the spiral shape, it is possible to form a long pipe compared to a straight pipe within a given space. Because the pipe 150a can be made long, the probability of collision of the HTB molecules and the TEOS molecules increases, and it is possible to obtain the effect of advancing the reaction of the HTB and the TEOS. In this case, a heating means 150b formed by a heater, for example, covers the pipe 150a. This heating means 150b corresponds to the heating means 100b of the embodiment 1. The heating means 150b is connected to the control unit 30A shown in FIG. 12 via the connecting means L to control the amount of heating so that the first vapor source and the second vapor source within the pipe 150a have a desired temperature, similarly as in the case of the embodiment 1. Further, it is preferable that the heating is made to a temperature similar to that of the embodiment 1.

### Embodiment 3

When causing the pre-reaction by the pre-reaction means, a film formation on the inner walls of the reaction chamber, for example, may become a problem depending on the conditions of the pre-reaction. Hence, in order to suppress the amount of film formation on the inner walls of the reaction chamber, the pre-reaction means may be configured as follows, for example.

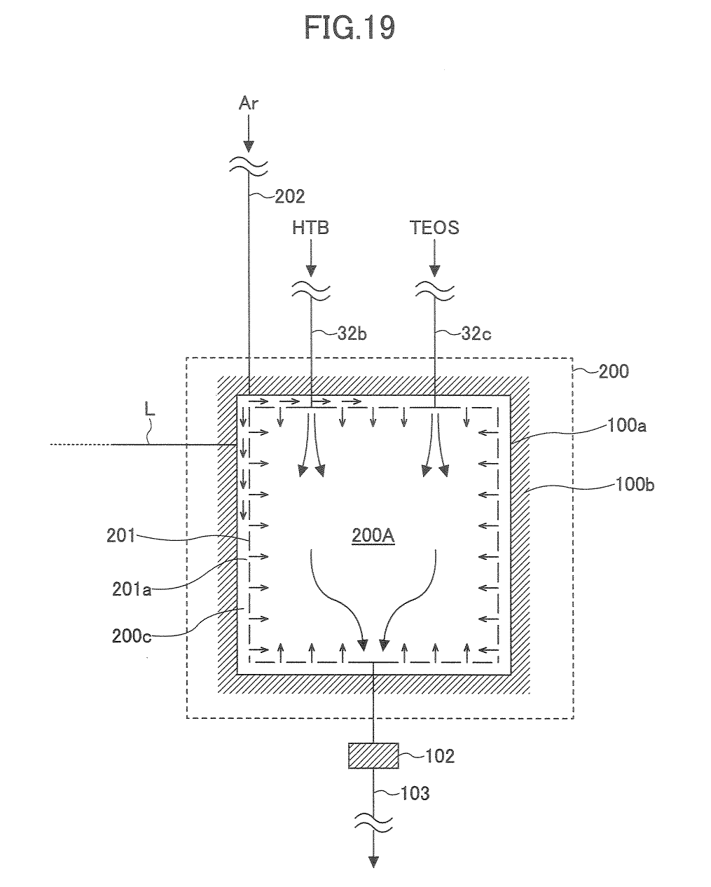

FIG. 19 is a diagram schematically showing a cross section of a pre-reaction means 200 in the embodiment 3 of the present invention. In FIG. 19, those parts that are the same as those of the preceding figures are designated by the same reference numerals, and a description thereof will be omitted.

As shown in FIG. 19, a pre-reaction means 200 of this embodiment has the reaction chamber 100a and a multi-hole cylinder 201 that is inserted inside the reaction chamber 100a. The multi-hole cylinder 201 has an approximate cylindrical shape and a large number of gas ejection holes 201a formed in the wall thereof. Accordingly, the inside of the reaction chamber 100a has a double space structure including a reaction chamber 200A that is formed inside the multi-hole cylinder 201 and causes the pre-reaction, and a gas passage 200c that is formed between the multi-hole cylinder 201 and the reaction chamber 100a.

A purge gas line 202 is connected to the reaction chamber 100a, so as to introduce a purge gas made of an inert gas, such as Ar, into the gas passage 200c. The purge gas that is introduced into the gas passage 200c is ejected via the gas ejection holes 201a in the multi-hole cylinder 201 towards the reaction space 200A, and supplied to a vicinity of the inner wall surface of the multi-hole cylinder 201.

For this reason, the reaction of the first vapor source and the second vapor source in the vicinity of the inner wall surface of the multi-hole cylinder is suppressed, and the decomposition of the first vapor source in the vicinity of the inner wall surface of the multi-hole cylinder is suppressed, so that it is possible to prevent deposits or sediments from adhering to the inner wall surface of the multi-hole cylinder.

In this case, the first vapor source and the second vapor source are supplied towards the reaction space 200A from the wall surface of the multi-hole cylinder 201, but the configuration is not limited to such. For example, it is possible to supply the first vapor source and the second vapor source to the gas passage 200c, mix the purge gas, the first vapor source and the second vapor source, and supply the mixture gas to the reaction space 200A via the gas ejection holes 201a.

In this case, it is possible to increase the rejection velocity of the mixture gas by making the gas ejection holes 201a small, and suppress the amount of deposits and sediments that adhere to the inner wall surface of the multi-hole cylinder.

### Embodiment 4

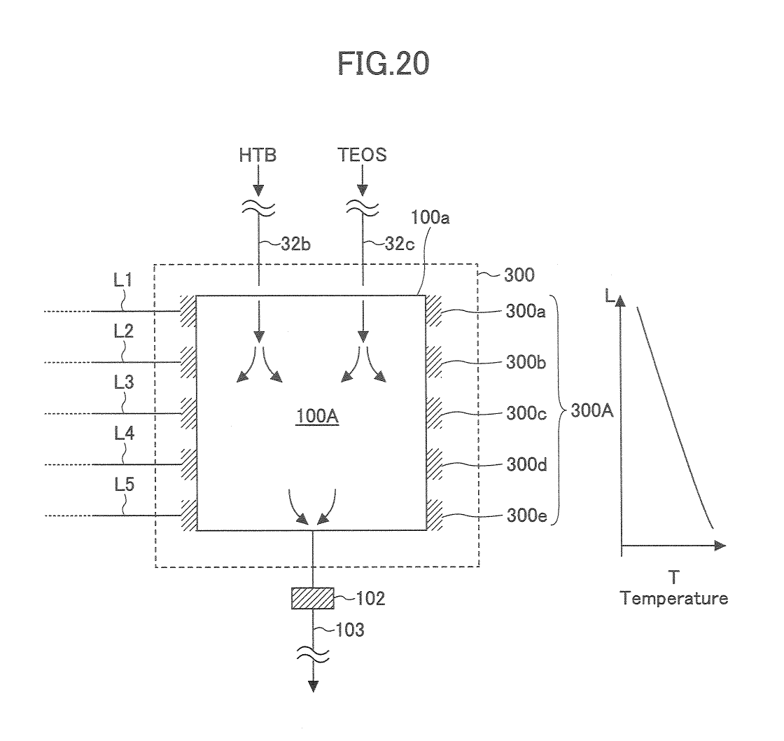

FIG. 20 is a diagram schematically showing a cross section of a pre-reaction means 300 in the embodiment 4 of the present invention. In FIG. 20, those parts that are the same as those of the preceding figures are designated by the same reference numerals, and a description thereof will be omitted.

In the pre-reaction means 300 of this embodiment, a heating means 300A is provided on the outer side of the reaction chamber 100a. The heating means 300A is configured to heat the first vapor source and the second vapor source, so that there is a temperature profile from a first side of the pre-reaction means where the gas lines 32b and 32c for introducing the first vapor source and the second vapor source are provided towards a second side of the pre-reaction means where the supply line 103 for exhausting the first vapor source and the second vapor source is provided.

FIG. 20 also shows a temperature distribution of the pre-reaction means 300 in a direction in which the first vapor source and the second vapor source flow. In this case, the temperature of the pre-reaction means 300 increases from the first side of the pre-reaction means where the gas lines 32b and 32c for introducing the first vapor source and the second vapor source are provided towards the second side of the pre-reaction means where the supply line 103 for exhausting the first vapor source and the second vapor source is provided.

Because the temperature of the first vapor source and the second vapor source gradually increases in the direction which the first vapor source and the second vapor source flow, it is possible to efficiently generate the precursor (HTB′-TEOS)′ or the precursor (HTB′-(TEOS))″, and to suppress the amount of film formation on the inner wall surface of the reaction chamber 100a.

There are various techniques for realizing the above described temperature profile in the pre-reaction means 300, but according to one example, the heating means 300A may be segmented as shown in FIG. 20.

The heating means 300A is segmented into a plurality of segments, and includes a heater 300a, a heater 300b, a heater 300c, a heater 300d and a heater 300e in this order from the first side where the first vapor source and the second vapor source are supplied towards the second side where the first vapor source and the second vapor source are exhausted.

The heaters 300a through 300e are connected to the control unit 30A shown in FIG. 12 via corresponding connecting means L1 through L5, and each of the heaters 300a through 300e is controlled by the control unit 30A so that the desired temperature profile is obtained.

The number of heater segments, the arrangement of the heater segments, the heating medium and the like are of course not limited to the above, and various variations and modifications may be made.

### Embodiment 5

The film forming apparatus to which the present invention may be applied, is not limited to the film forming apparatus 30 of the embodiment 1 shown in FIG. 12, and effects similar to those obtainable in the embodiment 1 can be obtained even when the present invention is applied to various other film forming apparatuses.

For example, although the film forming apparatus 30 is the so-called single wafer type film forming apparatus that processes one to-be-processed substrate at a time, the present invention is similarly applicable to other types of film forming apparatuses (sometimes referred to as furnace type film forming apparatus, vertical furnace type film forming apparatus, horizontal furnace type film forming apparatus or, batch type film forming apparatus) that simultaneously processes a plurality of to-be-processed substrates, such as several tens to several hundred to-be-processed substrates.

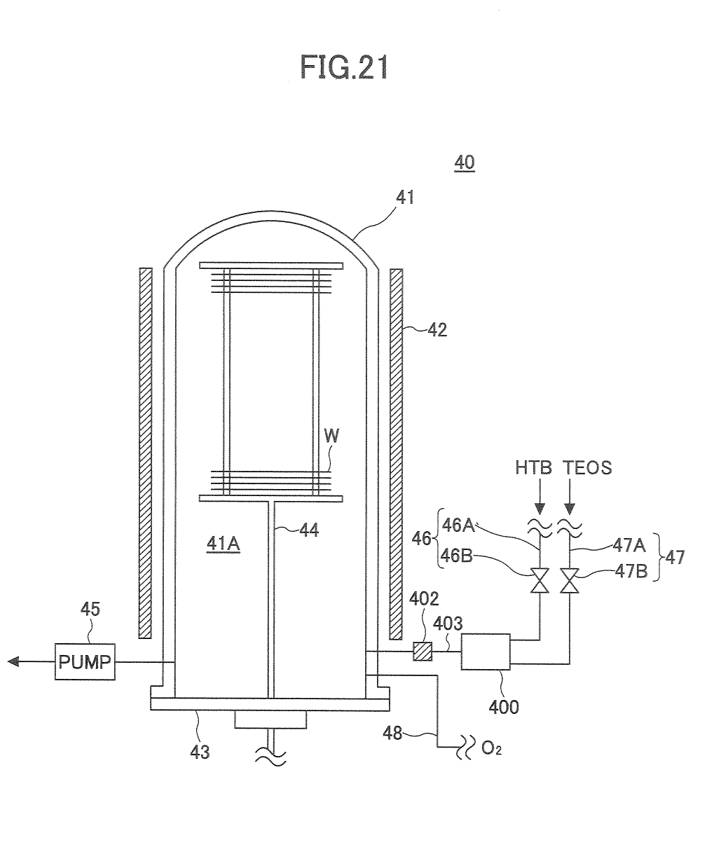

FIG. 21 schematically shows a cross section of a vertical furnace type film forming apparatus 40 in the embodiment 5 of the present invention.

As shown in FIG. 21, the film forming apparatus 40 of this embodiment generally has a reaction tube 41 made of quartz, for example, and a substrate holding structure 44 that is provided inside the reaction tube 41 and is configured to hold a plurality of to-be-processed substrates W.

The substrate holding structure 44 holds several tens to several hundred to-be-processed substrates W that are successively set in a direction in which the reaction tube 41 extends.

The substrate holding structure 44 is supported by a lid part 43 that closes and seals an opening of the reaction tube 41. The lid part 44 is connected to an elevator means that is not shown, and is moved up and down by the elevator means. In other words, the elevator means enables the extraction of the substrate holding structure 44 from the reaction tube 41 and the insertion of the substrate holding structure 44 into the reaction tube 41.

A heating means 42 is provided in a periphery of the reaction tube 41. A processing space 41A that is formed inside the reaction tube 41 can be put into a decompression state by an exhaust means 45.

The film forming apparatus 40 of this embodiment can carry out a film forming process similarly to the film forming apparatus 30 of the embodiment 1, for example.

For example, a gas line 48 is provided to supply oxygen gas to the processing space 41A. There are further provided a first gas supplying means 47 for supplying into the processing space 41A a first vapor source including a metal alkoxide (for example, HTB) having a tertiary butoxyl group as a ligand, and a second gas supplying means 48 for supplying into the processing space 41A a second vapor source including a silicon alkoxide source (for example, TEOS).

The first gas supplying means 46 includes a gas line 46A and a valve 46B, and a configuration similar to that used in the embodiment 1, for example, may be used to connect the gas line 46A. The second gas supplying means 47 includes a gas line 47A and a valve 47B, and a configuration similar to that used in the embodiment 1, for example, may be used to connect the gas line 47A.

The first gas supplying means 46 and the second gas supplying means 47 are connected to a pre-reaction means 400 for causing pre-reactions of the first vapor source and the second vapor source. The first vapor source and the second vapor source after the pre-reactions caused by the pre-reaction means 400 are supplied from the pre-reaction means 400 to a processing space 41B via a supply line 403. A pressure adjusting means 402 may be connected to the supply line 403.

The pre-reaction means 400 and the pressure adjusting means 402 of this embodiment respectively correspond to the pre-reaction means 100 and the pressure adjusting means 102 of the embodiment 1. The pre-reaction means 400 and the pressure adjusting means 402 are configured similarly to those of the embodiment 1, and effects similar to those obtainable in the embodiment 1 are also obtainable in this embodiment when forming the film.

In other words, similarly to the embodiment 1, this embodiment can obtain the effect of suppressing the amount of film formation occurring with respect to portions other than the to-be-processed substrates W within the reaction tube 41, and efficiently conveying the precursors to the to-be-processed substrates W.

Consequently, it is possible to suppress the generation of particles that occurs when the film formed within the reaction tube 41 separates, for example, and it is possible to form the film in a clean environment, similarly to the embodiment 1. In addition, by suppressing the film formation within the reaction tube, it is possible to reduce the maintenance intervals of the apparatus and to improve the rate of operation of the apparatus, so as to efficiently form the film. Moreover, since the utilization efficiency of the sources improves, it is possible to suppress the amount of sources consumed, and to reduce the cost of forming the film. Particularly in the case of the furnace type film forming apparatus, the precursors must be conveyed over a long distance when compared to the single wafer type film forming apparatus, and for this reason, the present invention which suppresses the film formation on the inner walls of the reaction tube and efficiently conveys the precursors to the to-be-processed substrates is especially effective.

### Embodiment 6

In the film forming apparatus 30 of the embodiment 1 shown in FIG. 12, the pre-reaction means is not limited to that described above, and other methods may be employed to suppress the amount of film formation at portions other than the to-be-processed substrate, such as the amount of film formation on the shower head 32S.

For example, in the film forming apparatus 30, a distance (hereinafter referred to as a gap) between the shower head 32S and the to-be-processed substrate that is held on the holding base 32A may be optimized, and a flow rate of an assist gas that dilutes the source gas supplied from the supply line 102 may be optimized, so as to suppress the amount of film formation on the shower head 32S. The assist gas is N₂ gas, for example, and is supplied to the shower head 32S from the gas line 34 that is connected to the supply line 102, so as to dilute the source gas.

The present inventors have conducted the following experiment using the film forming apparatus 30, and made a simulation based on the results of the experiment, so as to compute the optimum ranges for the gap and the flow rate of the assist gas described above. But in the experiment described below, no TEOS was used, and for this reason, the pre-reaction means substantially did not function.

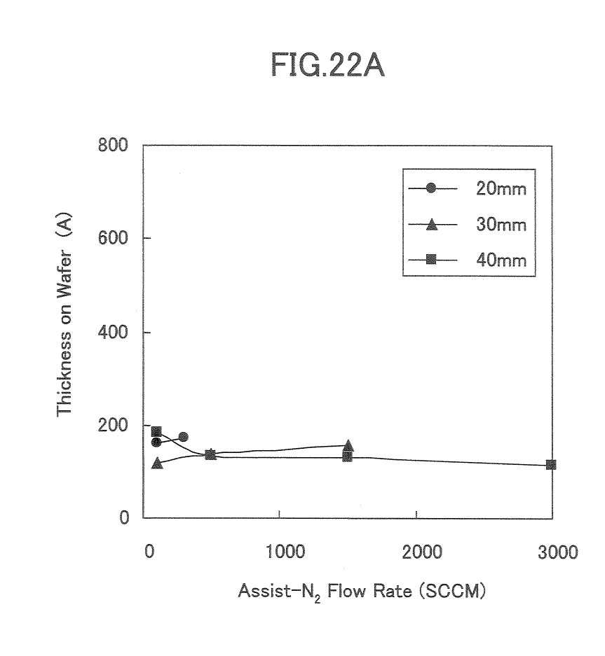

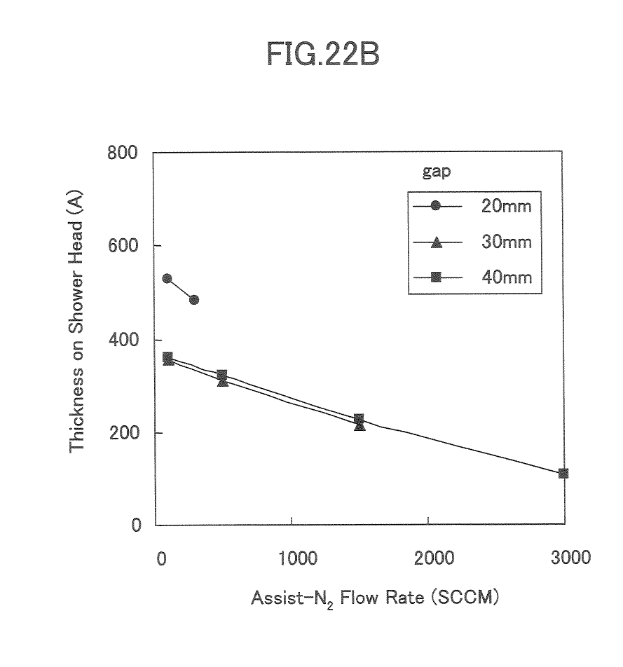

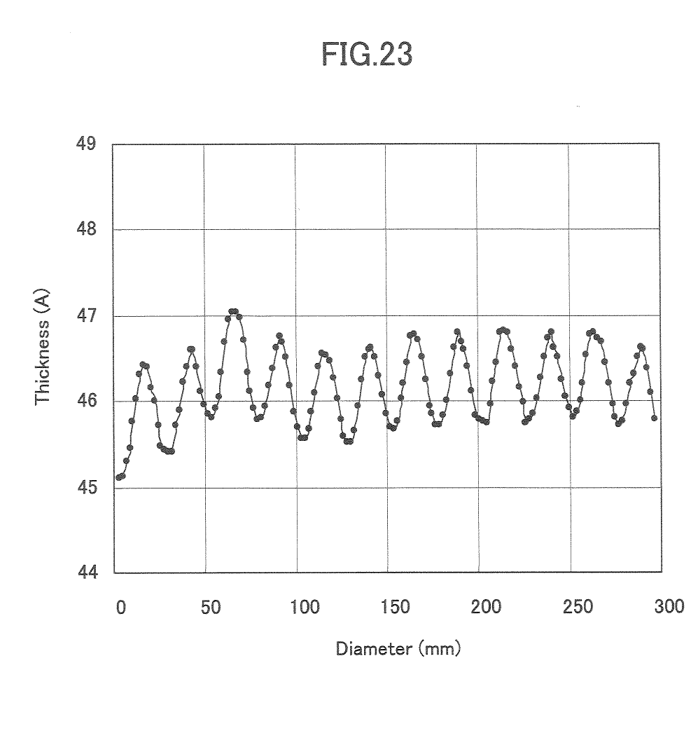

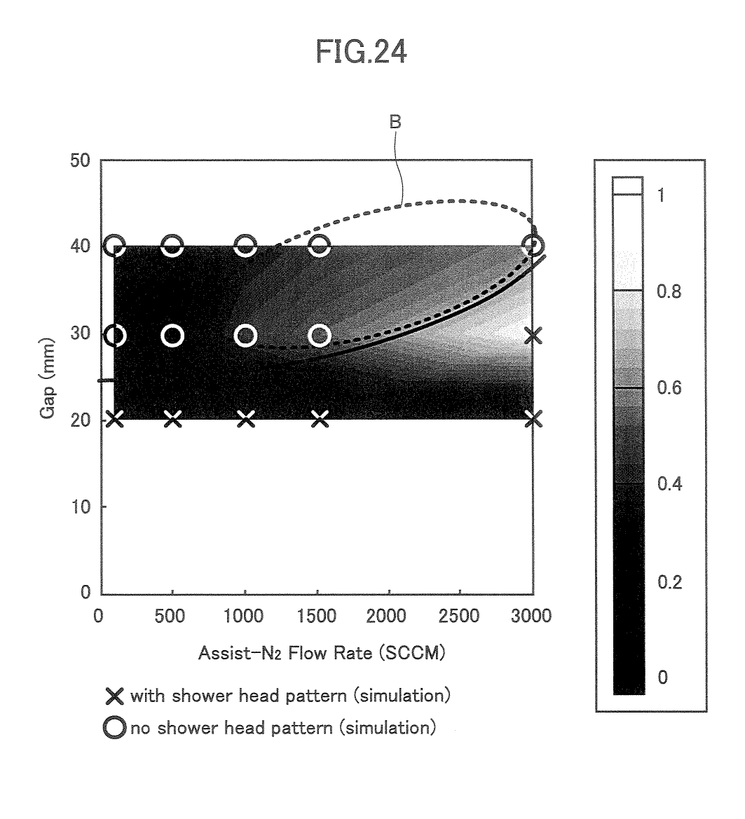

FIGS. 22A, 22B and 23 show the results of the experiment using the film forming apparatus 30, and FIG. 24 shows the results of the simulation based on the results of the experiment. The simulation results were obtained with respect to a HfO₂ film that is formed by using HTB and oxygen gas, and no Si was added.

FIGS. 22A and 22B show the thickness of the HfO₂ film that is deposited using the film forming apparatus 30 when the flow rate of the assist gas is changed. FIG. 22A shows the deposited film thickness on the to-be-processed substrate, and FIG. 22B shows the deposited film thickness on the shower head 32S. In this case, nitrogen (N₂) is used for the assist gas, and the gap was changed to 20 mm 30 mm and 40 mm.

As may be seen from FIGS. 22A and 22B, the deposited film thickness on the to-be-processed substrate virtually does not change when the gap is changed in the range of 20 mm to 40 mm. In addition, even when the flow rate of the assist gas is changed in the range of 30 SCCM to 3000 SCCM, the effect of this change is small, and the amount of change in the deposited film thickness on the to-be-processed substrate is small.

On the other hand, in the case of the deposited film thickness on the shower head 32S, the thickness decreases for the gaps of 30 mm and 40 mm when compared to the gap of 20 mm. in addition, as the flow rate of the assist gas is increased from 30 SCCM to 3000 SCCM, the deposited film thickness decreases. For this reason, it may be seen that, in order to suppress the amount of film formation on the shower head, it is preferable to make the gap wide and to increase the flow rate of the assist gas. By widening the gap, it becomes possible to separate from the shower head the region where the source gas ejected from the openings 32P are heated and decomposed, and to suppress the film formation on the shower head. Moreover, the ejection velocity of the source gas ejected from the openings 32P increases when the flow rate of the assist gas is increased, and as a result, the time for which the source gas molecules are heated in the space before reaching the to-be-processed substrate decreases, and the decomposition of the source gas is suppressed.

On the other hand, the experiment also revealed another problem when the gap is narrowed or the flow rate of the assist gas is increased.

FIG. 23 shows a film thickness distribution of a HfO₂ film that is deposited on the to-be-processed substrate using the film forming apparatus 30 shown in FIG. 12. The film thickness distribution is shown for a diametrical direction passing the center of the to-be-processed substrate, by taking one point at one end portion of the to-be-processed substrate as a reference (0), and setting a distance between this reference and the other end portion confronting the one end portion via the center to 300 mm. In addition, the gap is set to 20 mm, and the flow rate of the assist gas is set to 30 SCCM.

As may be seen from FIG. 23, the film thickness has a distribution such that a thick portion and a thin portion alternately occur along the diametrical direction. It may be regarded that this reflects the shape of the openings 32P in the shower head 32S shown in FIG. 12. As shown, when the gap is narrow, the shape (pattern) of the openings in the shower head from which the gas is ejected becomes reflected to the film thickness (this phenomenon will hereinafter be referred to as a pattern transfer), and there is a problem in that a desired film thickness distribution cannot be obtained. For example, it has been confirmed that such a pattern transfer occurs when the gap is 20 mm or narrower. In addition, it has also be confirmed that such a pattern transfer occurs when the flow rate of the assist gas is increased to increase the gas ejection velocity. It is possible to know from simulation whether or not a pattern transfer will occur, but a detailed description of such a simulation will be given later.

In order to suppress the generation of the pattern transfer, one conceivable method is to widen the gap. However, if the gap is set to 50 mm or wider, it has been confirmed from simulation that a desired film formation rate cannot be obtained because the amount of film formed on the to-be-processed substrate will decrease even when the flow rate of the assist gas is increased to increase the gas ejection velocity.

On the other hand, if the flow rate of the assist gas is excessively increased, the effect of diluting the source gas becomes large, and there is a problem in that the amount of firm formation on the to-be-processed substrate decreases.

FIG. 24 shows the optimum ranges for the gap size and the flow rate of the assist gas that are based on the simulation results in view of the results of the experiment described above. FIG. 24 shows the computation results of the simulation in a range of 0 to 1, for a ratio (hereinafter referred to as a film formation ratio) of the amount of film formation on the shower head with respect to the amount of film formation on the to-be-processed substrate, when the gap size and the flow rate of the assist gas are changed. FIG. 24 also shows the existence of the transfer pattern obtained by the simulation results. In FIG. 24, a symbol “X” indicates that the transfer pattern exits, and a symbol “O” indicates that the transfer pattern does not exist.

From the simulation results, the results of the above described experiment, and the analysis of theses results, it may be seen that the gap size and the flow rate of the assist gas are preferably in a range indicated by a region B. For example, it was found that the gap is preferably in a range of 30 mm to 40 mm. This is because, if the gap is less than 30 mm (for example, 20 mm), it became clear from the experiment and the simulation results that the pattern transfer will occur, and if the gap exceeds 40 mm (for example, 5 mm), it became clear from the simulation results that the desired film formation rate cannot be obtained.

For example, if the gap is 30 mm in the case described above, it is preferable that the flow rate of the assist gas is set in a range of 1000 SCCM to 1500 SCCM. This is because, such a flow rate range enables the amount of film formation on the shower head (film formation ratio) to be suppressed while suppressing the generation of the pattern transfer. Similarly, if the gap is 40 mm, for example, it is preferable that the flow rate of the assist gas is set in a range of 1500 SCCM to 3000 SCCM. This is because, such a flow rate range enables the amount of film formation on the shower head (film formation ratio) to be suppressed while suppressing the generation of the pattern transfer.

Although the embodiments were described for the formation of the HfO₂ film, it is also possible to form a Hf silicate film by further adding TEOS as the source gas. in addition, the effect of preventing the film formation on the shower head increases by appropriately combining the embodiments 1 through 5.

Further, the present invention is not limited to these embodiments, but various variations and modifications may be made without departing from the scope of the present invention.

### INDUSTRIAL APPLICABILITY

According to the present invention, it is possible to enable a film formation by MOCVD, with a satisfactory utilization efficiency of the source gas and a high productivity.

This international application claims priority based on a Japanese Patent Application No. 205-107667 filed Apr. 4, 2005, and the entire content of the Application No. 2005-207667 is incorporated herein by reference in this international application.

1. A film forming apparatus characterized in that there are provided:
a processing chamber for holding therein a to-be-processed substrate;
a first gas supplying means for supplying into the processing chamber a first vapor source including a metal alkoxide having a tertiary butoxyl group as a ligand; and
a second gas supplying means for supplying into the processing chamber a second vapor source including a silicon alkoxide source,
wherein the first gas supplying means and the second gas supplying means are connected to a pre-reaction means for causing pre-reactions of the first vapor source and the second vapor source, and the film forming apparatus is configured to supply the first vapor source and the second vapor source after the pre-reactions into the processing chamber.

2. The film forming apparatus as claimed in claim 1, characterized in that the pre-reaction means includes a heating means for heating the first vapor source and the second vapor source.

3. The film forming apparatus as claimed in claim 2, characterized in that the heating means heats the first vapor source and the second vapor source, so that there is a temperature profile from a first side of the pre-reaction means where the first vapor source and the second vapor source are introduced towards a second side of the pre-reaction means where the first vapor source and the second vapor source are exhausted.

4. The film forming apparatus as claimed in claim 1, characterized in that there is provided a pressure adjusting means for adjusting pressures of the first vapor source and the second vapor source that are caused to make pre-reactions by the pre-reaction means.

5. The film forming apparatus as claimed in claim 4, characterized in that the pressure adjusting means includes a conductance adjusting means that is provided in a supply passage through which the first vapor source and the second vapor source after the pre-reaction are supplied into the processing chamber.

6. The film forming apparatus as claimed in claim 1, characterized in that the pre-reaction means includes a spiral pipe in which the first vapor source and the second vapor source are mixed.

7. The film forming apparatus as claimed in claim 1, characterized in that the pre-reaction means includes a reaction chamber containing a reaction space in which the first vapor source and the second vapor source are mixed.

8. The film forming apparatus as claimed in claim 7, characterized in that the reaction chamber is separated and partitioned from an internal space within the processing chamber.

9. The film forming apparatus as claimed in claim 7, characterized in that inner walls of the reaction chamber include a plurality of gas supplying holes for supplying an inert gas to a vicinity of surfaces of the inner walls.

10. The film forming apparatus as claimed in claim 1, characterized in that the first vapor source includes hafnium tetratertiary butoxide, and the second vapor source includes tetraethylortho silicate.

11. The film forming apparatus as claimed in claim 10, characterized in that there are provided:
a heating means, provided in the pre-reaction means, for heating the first vapor source and the second vapor source; and
a control means for controlling the heating means to heat the first vapor source and the second vapor source to a temperature of 110° C. to 250° C.

12. A film forming method for forming a metal silicate film on a silicon substrate by metal organic CVD, characterized in that there are provided:
a first step causing pre-reactions of a first vapor source including a metal alkoxide having a tertiary butoxyl group as a ligand and a second vapor source including a silicon alkoxide source, and generating a precursor used for a film formation; and
a second step supplying the precursor onto the silicon substrate and forming the metal silicate film.

13. The film forming method as claimed in claim 12, characterized in that the first step heats the first vapor source and the second vapor source.

14. The film forming method as claimed in claim 12, characterized in that the first vapor source includes hafnium tetratertiary butoxide, and the second vapor source includes tetraethylortho silicate.

15. The film forming method as claimed in claim 13, characterized in that the first vapor source includes hafnium tetratertiary butoxide, the second vapor source includes tetraethylortho silicates and the first step heats the first vapor source and the second vapor source to a temperature of 110° C. to 250° C.

16. A recording medium recorded with a program for causing a computer to carry out a film forming method in a film forming apparatus comprising:
a processing chamber for holding therein a to-be-processed substrate;
a first gas supplying means for supplying into the processing chamber a first vapor source including a metal alkoxide having a tertiary butoxyl group as a ligand;
a second gas supplying means for supplying into the processing chamber a second vapor source including a silicon alkoxide source; and
a pre-reaction means for causing pre-reactions of the first vapor source and the second vapor source,
characterized in that the film forming method comprises:
a first step supplying the first vapor source and the second vapor source to the pre-reaction means and causing pre-reactions of the first vapor source and the second vapor source; and
a second step supplying the first vapor source and the second vapor source after the pre-reactions into the processing chamber, so as to solve the problem described above.

17. The recording medium as claimed in claim 16, characterized in that the pre-reaction means includes a heating means, and the first step heats the first vapor source and the second vapor source.

18. The recording medium as claimed in claim 16, characterized in that the first vapor source includes hafnium tetratertiary butoxide, and the second vapor source includes tetraethylortho silicate.

19. The recording medium as claimed in claim 17, characterized in that the first vapor source includes hafnium tetratertiary butoxide, the second vapor source includes tetraethylortho silicate, and the first step heats the first vapor source and the second vapor source to a temperature of 110° C. to 250° C.
